(19) United States
(12) Patent Application Publication
(10) Pub. No.: US 2026/0016506 A1
(43) Pub. Date: Jan. 15, 2026

(54) PROBE PROCESSING APPARATUS AND METHOD FOR PROCESSING PROBES

(71) Applicants: MESOSCOPE TECHNOLOGY CO., LTD., HSINCHU CITY (TW); QUATERNITY INDUSTRIAL TECH CO., LTD., HSINCHU CITY (TW); TRINITY ANALYSIS TECH CO., LTD., HSINCHU CITY (TW)

(72) Inventor: HSIN-HAU HUANG, HSINCHU CITY (TW)

(21) Appl. No.: 19/259,918

(22) Filed: Jul. 3, 2025

(30) Foreign Application Priority Data
Jul. 11, 2024 (TW) 113126009
Apr. 1, 2025 (CN) 202510400392.9

(51) Int. Cl. G01R 3/00

(52) U.S. Cl. CPC G01R 3/00

(57) ABSTRACT

The present disclosure relates to a probe processing apparatus and a method for processing probes. The probe processing apparatus includes a probe seat, a pushing element, and a stopping element, wherein the pushing element and the stopping element are positioned at different heights. The probe seat includes an opening configured to secure a probe. The pushing element is disposed on a first bracket positioned on one side of the probe seat, while the stopping element is disposed on a second bracket positioned on the opposite side of the probe seat. During the processing procedure, one end of the pushing element contacts the probe and applies pressure, causing the probe to bend towards the stopping element.

### PRIORITY CLAIM AND CROSS-REFERENCE

The present application claims priority to and the benefit of China Application No. 202510400392.9 filed on 1 Apr. 2025 and Taiwan Application TW113126009 filed on 11 Jul. 2024. The entirety of the above-mentioned patent applications is hereby incorporated by reference herein and made a part of specification.

### BACKGROUND

### 1. Field of the Disclosure

The present disclosure relates to a probe processing apparatus, and more particularly to a probe processing apparatus configured to perform bending processing on probes.

### 2. Description of Related Art

Probes are commonly used in the manufacturing and analysis processes of semiconductor components, particularly for detecting structures, dimensions, material properties, or potential defects in items such as chips, wafers, transistors, integrated circuits, or other micro-nano-scale electronic components. Different technical fields may have varying detection requirements, such as structural analysis or electrical testing. For example, an electron beam can be used to scan the surface of the object back and forth. By observing the reflected or transmitted light, the surface features (e.g., the shape of undulations) of the object can be detected, thereby detecting surface features of the object.

In conventional detection processes, linear-type probes are often used. The tips of these linear probes typically contact and press against the electrodes of micro-nano components at a fixed inclination angle, forming a rigid contact state. Since the contact force is difficult to control precisely, the probe tip tends to slide a certain distance on the electrode surface during the transition from initial contact to full pressing. This sliding causes irreversible damage to the electrode, reducing the number of times the micro-nano component can be tested, and hindering in-depth research on its reliability. The main reasons for this are: (1) the electrodes of micro-nano components are extremely thin, with thicknesses of only several tens of nanometers; and (2) the adhesion between the electrodes and the substrate is relatively weak.

Therefore, in the industry, linear probes are often bent to meet varying detection requirements and testing environments. In such configurations, even when the probe is inclined, its tip can still make vertical and secure contact with the electrode surface of the micro-nano component. When the contact force becomes too great, the probe deflects slightly, creating an elastic contact with the micro-nano component. This elastic interaction helps reduce the sliding distance of the probe tip on the electrode surface, thereby minimizing potential damage. Such a design not only preserves the integrity of the electrode surface but also increases the number of tests that can be performed on the micro-nano component, enhancing both the reliability and efficiency of detection.

For example, China patent No. CN219093456U discloses a device specifically for bending alloy probe tips. The structure of the device includes an iron base and multiple fixing screws. First and second upper iron bases are connected to the two sides of the top surface of the iron base, leaving a gap between them where a probe is placed. Two sets of fixing screws pass through the iron base and are firmly connected to the first and second upper iron bases, respectively. The top surface of the first upper iron base is designed as an inclined surface, the angle of which corresponds closely to the desired bending angle of the probe. This device replaces the traditional single-sided spring force or pneumatic force with a manually operated double-sided sharp-angled pressing mechanism, thereby reducing the risk of tip fracture after bending.

With the rapid advancement of semiconductor technology, the dimensions of the components to be measured by probes have been reduced to 40 nanometers, 14 nanometers, or even smaller. However, conventional probe processing apparatuses can no longer meet the industry's demand for producing bent probes with consistent and stable quality. This inadequacy can adversely affect the durability of probes in subsequent processing. Specifically, during conventional deformation processing of probes, it is difficult to securely clamp the workpiece (e.g., the probe), resulting in angular deviations during deformation process and significantly compromising the bending outcome. In other words, conventional probe processing apparatuses are unable to meet the stringent conditions required by advanced semiconductor processes, making it difficult to achieve mass production of bent probes with consistent and stable quality.

In summary, how to provide bent probes with consistent and stable quality while meeting the requirements of advanced semiconductor processes has become an urgent issue in the industry. In view of this, the present disclosure provides a processing apparatus applicable to workpieces such as probes. Specifically, the disclosed probe processing apparatus is suitable not only for probes with dimensions below 7 nanometers but also for angstrom-scale probes or electrodes. The disclosed probe processing apparatus is also configured to ensure consistency and stability during the processing, thereby satisfying the high standards of modern semiconductor manufacturing.

### SUMMARY

The present disclosure primarily provides a probe processing apparatus for bending probes, a probe processing system equipped with the probe processing apparatus, and a method for processing probes. The disclosed probe processing apparatus is configured to securely fix the probe and precisely aligns with it during processing, thereby ensuring consistency and stability in the bending of the probe throughout the process.

An exemplary embodiment of the present disclosure provides a probe processing apparatus, which comprises a probe seat, a pushing element, and a stopping element. The probe seat has an opening configured to secure a probe therein. The pushing element is disposed on a first bracket disposed on a first side of the probe seat and configured to move relative to the probe seat. The stopping element is disposed on a second bracket, and the second bracket is positioned on a second side opposite to the first side of the probe seat and configured to press against the probe fixed on the probe seat. In addition, the pushing element and the stopping element are disposed at different heights. During the processing operation, one end the pushing element contacts and applies pressure on the probe, so that the probe is bent toward the stopping element.

An exemplary embodiment of the present disclosure provides a probe processing apparatus, which comprises a probe seat, a stopping element, and a pushing element. The probe seat is configured to hold a probe, wherein when the probe is held on the probe seat, the probe extends substantially in a vertical direction. In addition, when the probe is held on the probe seat, the stopping element is configured to abut the probe at a first height. The pushing element is configured to realize a movement in a horizontal direction, wherein when the stopping element abuts the probe, the pushing element is configured to contact and push the probe at a second height by the movement, so as to deform the probe. The second height is higher than the first height. Moreover, the probe comprises a probe used for detecting micro-nano components.

An exemplary embodiment of the present disclosure provides a method for processing a probe, comprising: holding a probe on a probe seat, wherein the probe held on the probe seat extends substantially in a vertical direction; providing a stopping element to abut the probe at a first height; providing a pushing element to contact the probe at a second height, wherein the second height is higher than the first height; and moving the pushing element in a horizontal direction such that the pushing element pushes the probe at the second height and deforms the probe; wherein the probe comprises a probe used for detecting micro-nano components.

### BRIEF DESCRIPTION OF THE DRAWINGS

Aspects of some embodiments of the present disclosure are readily understood from the following detailed description when read with the accompanying figures. It should be noted that various structures may not be drawn to scale, and dimensions of the various structures may be arbitrarily increased or reduced for clarity of discussion.

FIG. 1 is a schematic view of a probe processing apparatus in accordance with an embodiment of the present disclosure.

FIG. 2 is a side view of the probe processing apparatus in accordance with an embodiment of the present disclosure, illustrating a height adjusting assembly.

FIG. 3A is a partially enlarged schematic view 1 of the probe processing apparatus in accordance with an embodiment of the present disclosure, in which a pushing element and a stopping mechanism are respectively positioned on opposite sides of the probe.

FIG. 3B is partially enlarged schematic view 2 of the probe processing apparatus in accordance with an embodiment of the present disclosure, in which the pushing element and the stopping mechanism are respectively moving toward the probe.

FIG. 3C is partially enlarged schematic view 3 of the probe processing apparatus in accordance with an embodiment of the present disclosure, showing the probe being gradually bent toward the stopping mechanism.

FIG. 3D is a partially enlarged schematic view 4 of the probe processing apparatus in accordance with an embodiment of the present disclosure, showing the probe bent to be substantially parallel to the stopping mechanism.

FIG. 4A is a perspective partially enlarged schematic view of the probe processing apparatus in accordance with an embodiment of the present disclosure.

FIG. 4B is a perspective partially enlarged schematic view of the probe processing apparatus in accordance with another embodiment of the present disclosure.

FIG. 5 illustrates a structural design of the probe in accordance with an embodiment of the present disclosure, which is applicable to the probe processing apparatus above.

FIG. 6 is a schematic view showing the probe of the present disclosure used for detection of a micro-nano component.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that, although the terms first, second, etc., may be used herein to describe various elements, these elements should not be limited by these terms. Unless indicated otherwise, these terms are only used to distinguish one element from another element.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5% less than or equal to ±4%, less than or equal to ±3%, less than or equal to ±2%, less than or equal to: 1%, less than or equal to 1:0.5%, less than or equal to ±0.1%, or less than or equal to ±0.05%. For example, two numerical values can be deemed to be “substantially” the same as or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

As shown in the figures of the instant application, and in the following description of the embodiments, to facilitate explanation of the disclosure, xyz-coordinates will be used. The xyz-coordinates include an X-axis and a Y-axis and a Z-axis.

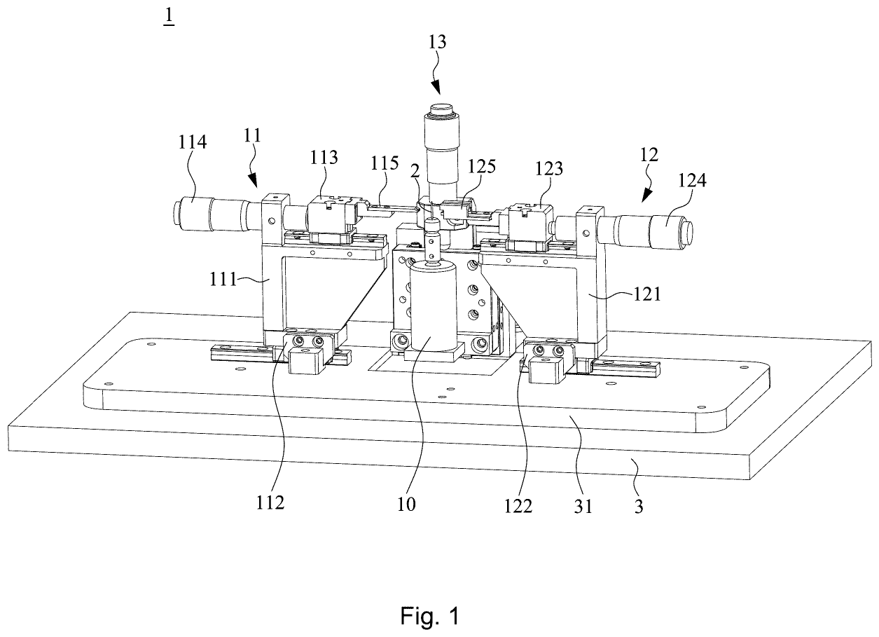

FIG. 1 illustrates a schematic view of a probe processing apparatus in accordance with an embodiment of the present disclosure. The probe processing apparatus 1 is applicable for performing various processing operations on a probe 2, such as bending, and may be mounted on a base 3. In some embodiments of the present disclosure, the base 3 may further include a grounded base 31, on which the probe processing apparatus 1 can be installed. The grounded base 31 may be fixed to the base 3 by locking or other securing mechanisms and may be made of suitable materials to effectively provide electrostatic discharge functionality for the probe 2, thereby preventing the adverse effects of static electricity on the probe. In some embodiments, the grounded base 31 may also be connected to an electrostatic discharge system (not shown) to further enhance the electrostatic discharge performance and ensure that the probe 2 is not affected by static interference during processing, thus improving the precision and safety of the process.

The probe 2 of the present disclosure may be a micro probe, nano probe, angstrom probe, or other type of probe used for detection of micro-nano components. In other embodiments, the probe processing apparatus 1 may be used to process other types of workpieces, such as optical alignment accessories, semiconductor detection consumables, integrated circuit testing consumables or accessories, probes, wires, electrodes, and other components.

The probe 2 may be a component made of metal or alloy and designed with a multi-stage taper having a continuously varying diameter in a symmetrical (isosceles) taper profile. In some embodiments, such a probe has symmetrical inclined or curved surfaces, with the angle of each inclined or curved surface ranging from 1 to 90 degrees and presenting a continuously tapering shape. In other embodiments, the probe 2 may be formed with asymmetrical inclined surfaces, resulting in a non-isosceles profile to meet various application requirements. Furthermore, in some embodiments, an array of such probes with multi-stage taper profiles may be formed on a substrate surface or arranged in bundled arrays.

A functional coating at the nanoscale may further be provided on the tip region of the probe 2 (not shown). This functional coating may serve various purposes including, but not limited to, improving wear resistance, enhancing conductivity, imparting magnetic properties, or enabling chemical functionalization of the tip for specific reactions in defined chemical environments. The wear-resistant coating may be made of hard metal alloys, such as titanium nitride (TiN), diamond, or diamond-like carbon (DLC). Conductive coatings may be formed from metals or metal alloys such as platinum (Pt), platinum-iridium (Pt—Ir), gold (Au), or nickel (Ni). Magnetic coatings may be made of metals or metal alloys such as cobalt (Co) or cobalt-chromium (Co—Cr). Additionally, to prevent adhesion when the probe comes into contact with sticky samples, anti-adhesive materials or particles may be selectively applied to the coating, based on workpiece requirements, to enhance anti-adhesion performance and ensure the stability and reliability of the probe during operation.

The probe processing apparatus 1 includes a probe seat 10, which may be used to receive the probe 2, ensuring its stability and precision during processing. As mentioned above, in certain embodiments, the probe processing apparatus 1 may also be used for processing other types of workpieces. In such cases, the probe seat 10 may be replaced with a specially designed holding mechanism for accommodating and securing other types of workpieces at predetermined processing positions. Specifically, the holding mechanism may take various forms, including but not limited to worktables, carrier plates, holders, substrates, panels, sheets, or cassettes. These various holding mechanisms can be selected and adjusted based on the characteristics and processing requirements of the different workpieces.

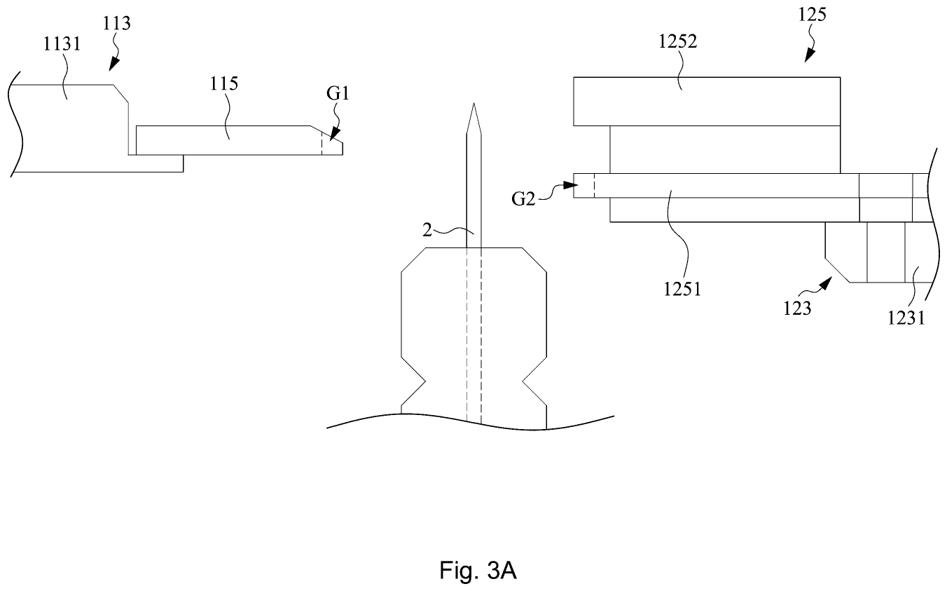

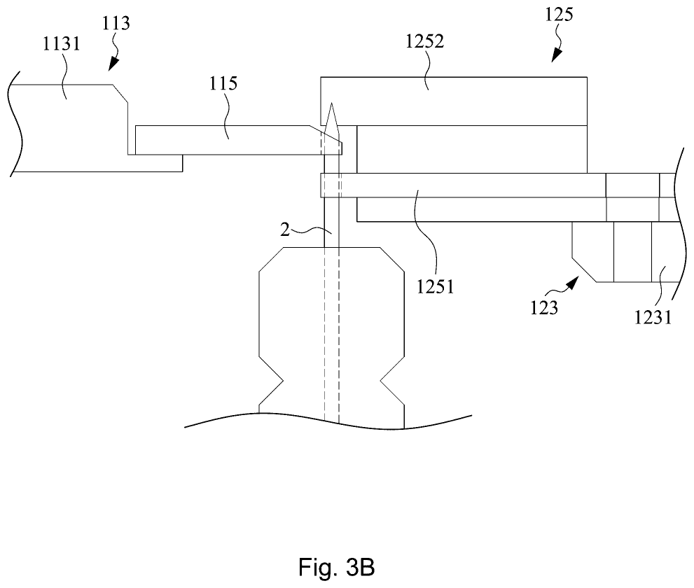

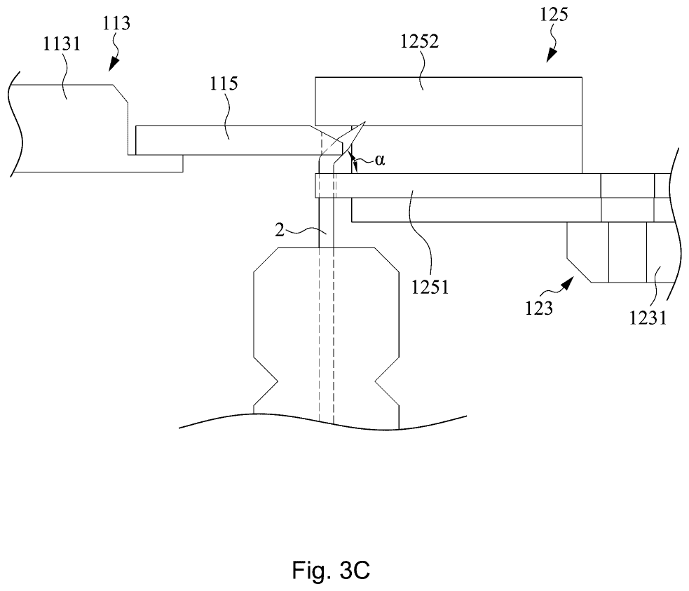

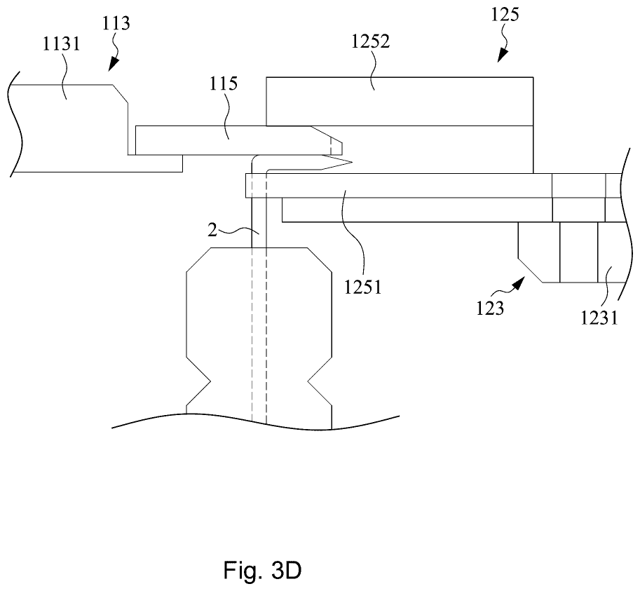

In practice, the probe seat 10 may accommodate the end portion of the probe 2 (see FIGS. 3A to 3D), thereby fixing the probe 2 to the probe processing apparatus 1 and ensuring the smooth execution of processing operations. As shown in the figures, when the probe 2 is held in the probe seat 10, the probe 2 may extend substantially in a vertical direction. Specifically, the probe seat 10 may include an opening (not shown) for receiving the probe 2 and a fitting component (not shown). The end portion and at least part of the body of the probe 2 may be constrained within the fitting component and secured in the opening. The fitting component may fix the probe 2 in place by a pressing fit, ensuring that it remains immobile during the processing. In some embodiments, the end portion of the probe 2 may be magnetic, and the probe 2 may be fixed in the probe seat 10 through magnetic attraction and/or vacuum suction. In other embodiments, at least one set screw may be installed inside the probe seat 10 and may abut the probe 2 to stabilize it (not shown). Furthermore, the probe 2 may also be manually fixed in the probe seat 10, or secured using other devices such as robotic arms, vibratory feeders, and suction systems for picking and placing the probe 2.

As shown in FIG. 1, the probe processing apparatus 1 includes a first processing assembly 11 and a second processing assembly 12, which are respectively disposed on opposite sides of the probe seat 10. The first processing assembly 11 includes a first bracket 111. In some embodiments, the first bracket 111 may be disposed on a first sliding base 112, which is configured to slide along a rail mounted on the grounded base 31, thereby allowing the first processing assembly 11 to move horizontally on the grounded base 31. A first sliding member 113 is arranged on the first bracket 111 and is configured to slide relative to the rail mounted on the first bracket 111. The first processing assembly 11 may further include a first displacement adjusting member 114, which passes through a through hole formed in the first bracket 111 and moves relative to the bracket. The end of the first displacement adjusting member 114 may press against the surface of the first sliding member 113, thereby enabling horizontal displacement of the first sliding member 113. In addition, a pushing element 115 is disposed on the side of the first sliding member 113 facing the probe seat 10.

Similar to the first processing assembly 11, the second processing assembly 12 includes a second bracket 121. In some embodiments, the second bracket 121 may be disposed on a second sliding base 122, which is configured to slide along a rail mounted on the grounded base 31, enabling horizontal movement of the second processing assembly 12 on the grounded base 31. A second sliding member 123 is arranged on the second bracket 121 and is configured to slide relative to the rail mounted on the second bracket 121. The second processing assembly 12 may further include a second displacement adjusting member 124, which passes through a through hole formed in the second bracket 121 and moves relative to the bracket. The end of the second displacement adjusting member 124 may press against the surface of the second sliding member 123, thereby enabling horizontal displacement of the second sliding member 123. Additionally, a stopping mechanism 125 is provided on the side of the second sliding member 123 facing the probe seat 10. As will be described later, the pushing element 115 and the stopping mechanism 125 may cooperate to perform processing operations on the probe 2.

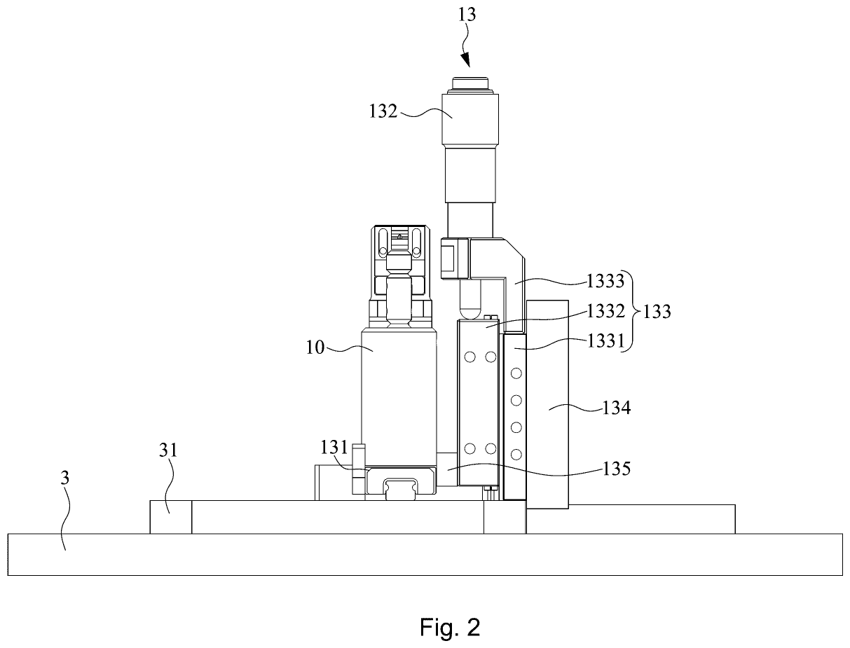

Please refer to FIGS. 1 and 2. FIG. 2 illustrates the height adjusting assembly 13 of the present disclosure. The height adjusting assembly 13 includes a connecting plate 131, a height adjusting member 132, and a slide rail assembly 133. The slide rail assembly 133 further includes a slide rail base 1331 and a slide rail cover 1332. The probe seat 10 may be mounted on the connecting plate 131, which is connected to the slide rail assembly 133. In some embodiments, the connecting plate 131 may be connected to the slide rail cover 1332. Additionally, the slide rail assembly 133 may further include a connecting bracket 1333 disposed on the slide rail base 1331. The connecting bracket 1333 may be fixed to the slide rail base 1331 by locking or similar mechanisms, or may be integrally formed with the slide rail base 1331. Moreover, the slide rail base 1331 may be attached to a supporting plate 134 fixed to the base 3, and the supporting plate 134 serves to support the slide rail assembly 133. In some embodiments, the supporting plate 134 may be fixed to the grounded base 31. As further shown in FIG. 2, a linkage unit 135 is disposed between the probe seat 10 and the height adjusting assembly 13. One end of the linkage unit 135 is connected to the slide rail cover 1332, and the other end is connected to the probe seat 10. Thus, when the height adjusting member 132 performs a height adjustment, the probe seat 10 is driven to move in the same direction.

The height adjusting member 132 may pass through a through hole formed on the connecting bracket 1333, enabling relative movement with respect to the connecting bracket 1333. In some embodiments, the end of the height adjusting member 132 may press against the surface of the slide rail cover 1332 and push it to move. The slide rail base 1331 and the slide rail cover 1332 respectively include corresponding rails or sliding grooves with corresponding external contours, allowing the rails to slide within the grooves. In this way, when the user operates the height adjusting member 132 to move it upward or downward relative to the connecting bracket 1333, the slide rail cover 1332 moves relative to the slide rail base 1331, thereby achieving vertical height adjustment of the probe seat 10.

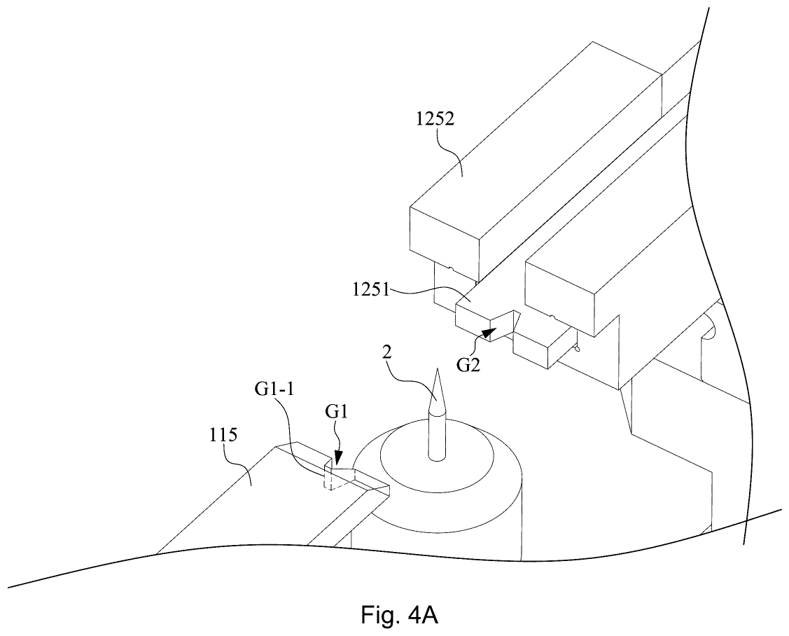

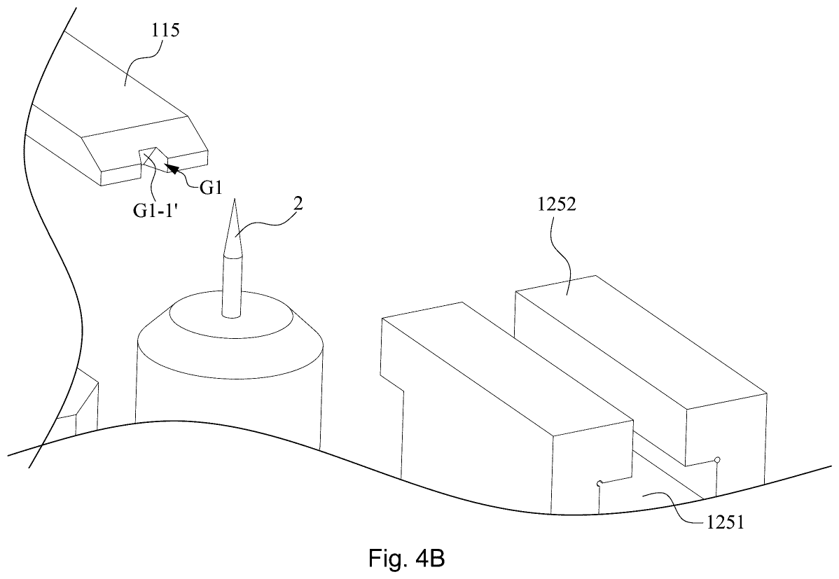

Please refer to FIGS. 1 and 3A to 3D. FIGS. 3A to 3D illustrate the process in which the probe processing apparatus 1 performs processing on the probe 2. The pushing element 115 may be mounted on a first connecting member 1131 of the first sliding member 113 by locking or similar mechanisms. The stopping mechanism 125 may include a stopping element 1251, which may also be mounted on a second connecting member 1231 of the second sliding member 123 by locking or similar mechanisms. In some embodiments, the stopping mechanism 125 may include a supporting member 1252 for carrying the stopping element 1251 (see FIG. 4A).

In practice, the user may operate the first displacement adjusting member 114 to drive the first sliding member 113, causing the pushing element 115 to move horizontally toward the probe 2 along a sliding rail. The user may also operate the second displacement adjusting member 124 to drive the second sliding member 123, such that the stopping mechanism 125 moves horizontally toward the probe 2. In some embodiments, the direction in which the pushing element 115 and the stopping mechanism 125 move is substantially orthogonal to the vertical direction in which the probe 2 extends.

In the embodiments of the present disclosure, power required for the driving components may be provided by a pneumatic cylinder, motor, or other similar power sources. Additionally, in some embodiments, the first processing assembly 11 or the second processing assembly 12 may include a damper or other functionally similar components. When the pushing element 115 and the stopping element 1251 respectively abut (or contact) the body of the probe 2, it indicates that the processing position of the probe 2 has been determined, and the system is ready for subsequent processing operations.

The pushing element 115 and the stopping element 1251 may be arranged at different heights. For example, the pushing element 115 may be disposed at a first height, while the stopping element 1251 is disposed at a second height, with the first height being greater than the second height. In some embodiments, the bottom surface of the pushing element 115 may be flush with the top surface of the stopping element 1251. In other words, the bottom surface of the pushing element 115 may be substantially aligned with the top surface of the stopping element 1251. Furthermore, the pushing element 115 and the stopping element 1251 may have different Young's modulus compared to the probe 2. For example, the Young's modulus of the pushing element 115 and the stopping element 1251 may be greater than that of the probe 2. Therefore, when the pushing element 115 and the stopping element 1251 respectively contact the probe 2 (as shown in FIG. 3B), pressure is applied to the body of the probe 2, causing the deform. During the pressure application process, the probe 2 gradually bends toward the stopping element 1251 (as shown in FIG. 3C) until it reaches a state substantially parallel to the top surface of the stopping element 1251 (as shown in FIG. 3D). During this process, an angle a is formed between the probe 2 and the stopping element 1251. In some embodiments, the angle a may range from approximately 0 to 90 degrees. Through the configuration of the above embodiments, the user may process the probe 2 to a desired angle according to actual requirements, thereby meeting customized demands of different users. In addition, each of the pushing element 115 and the stopping element 1251 may have a certain thickness at the side in contact with the probe 2, so as to prevent excessive pressure from being applied during the processing and damaging the probe body.

After the processing operation is completed, the user may further operate the probe processing apparatus to move the pushing element 115 and the stopping mechanism 125 away from the bent probe 2. In some embodiments, the first displacement adjusting member 114 and the second displacement adjusting member 124 may be operated to return the pushing element 115 and the stopping mechanism 125 to their initial positions (as shown in FIG. 3A).

Please refer to FIGS. 3A to 3D and FIG. 4A. FIG. 4A illustrates a partially enlarged schematic view of the probe processing apparatus 1 of the present disclosure. In some embodiments, the end of the pushing element 115 facing the probe seat 10 may be designed with a groove G1, and the end of the stopping element 1251 facing the probe seat 10 may be designed with a groove G2. These grooves G1 and G2 can respectively accommodate the body of the probe 2. In some embodiments, the groove Gl of the pushing element 115 and the groove G2 of the stopping element 1251 can be configured to respectively engage with the body of the probe 2 during the processing operation. With this configuration, when the pushing element 115 engages with the probe 2 via the groove G1 and applies pressure to its body, the body portion of the probe 2 engaged in the groove G2 of the stopping element 1251 serves as a support point. As the pressure gradually increases, the probe 2 bends gradually toward the stopping element 1251, thereby achieving the desired processing effect. In some embodiments, at least one of the grooves G1 and G2 may be approximately V-shaped (as shown in FIG. 4A). In other embodiments, at least one of the grooves G1 and G2 may also be approximately U-shaped. The configurations of the above embodiments allow the pressure applied to the probe 2 by the pushing element 115 and the stopping element 1251 during subsequent processing to be effectively dispersed. As a result, the processing of the probe 2 can be more precise, thereby improving both processing accuracy and efficiency. In addition, as shown in FIGS. 3A to 3D, there is a space between the top surface of the stopping element 1251 and the bottom surface of the supporting member 1252 that is equal to or greater than 0% to 2% of the probe diameter.

In some embodiments, alignment marks (not shown) smaller than the area of the grooves G1 and/or G2 can be further provided. These may optionally be formed within and/or outside the projected area of any of the grooves. The presence of such alignment marks facilitates better alignment by optical sensing elements (e.g., Charge Coupled Device, CCD), thereby improving precision and accuracy during the probe processing.

In some embodiments, the end of the pushing element 115 facing the probe seat 10 may be formed with an inclined surface, whereas the end of the stopping element 1251 facing the probe seat 10 may not include any inclined surface. This configuration can further enhance the stability of the probe 2 during the processing operation and effectively prevent displacement of the probe body during the bending process.

The stopping mechanism 125 may further include a supporting member 1252. The supporting member 1252 may be disposed on the second connecting member 1231 and may be configured to accommodate the stopping element 1251. In some embodiments, the supporting member 1252 may have a U-shaped opening (as better seen in FIG. 4A), such that the probe 2 is not interfered with by the supporting member 1252 during the bending process. Furthermore, in some embodiments, the supporting member 1252 may be integrally formed with the stopping element 1251. Through the configuration of the supporting member 1252, the stopping element 1251 can be more stably maintained during the probe 2 processing operation, thereby enhancing the precision and stability of the processing. As shown in FIG. 4A, the inner side of the groove G1 in the pushing element 115 may have a surface G1-1 that is perpendicular to both lateral edges. Also refer to FIG. 4B, which is a perspective partial enlarged schematic view of another embodiment of the probe processing apparatus 1 of the present disclosure. As shown in FIG. 4B, the inner side of the groove Gl in the pushing element 115 may alternatively have an inclined surface G1-1′ that is not perpendicular to both lateral edges. In some embodiments, the inclined surface G1-1′ may be inclined toward the probe 2, allowing the pushing element 115 to make better contact with the probe 2 during processing.

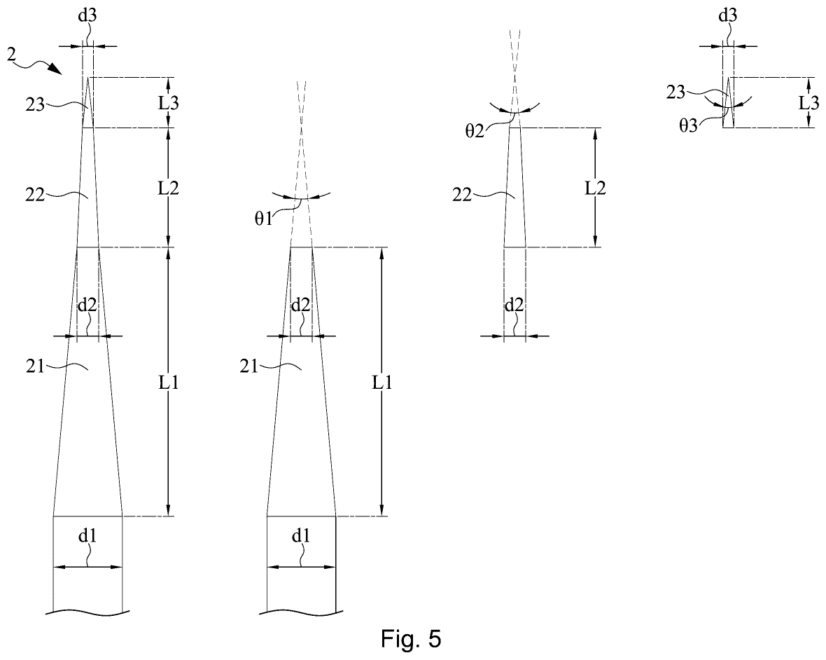

As previously described, in some embodiments, the probe 2 disclosed herein may be used for the detection of micro-nano components. In such cases, the design of the probe structure is theoretically a key factor in improving the accuracy of the detection process for micro-nano components. Please refer to FIG. 5, which illustrates the structure of the probe 2 in the present disclosure. The probe 2 may include multiple body segments and a tip segment, each differing in length and width. Here, the term “width” refers to the vertical distance from the center of the probe tip to the outer surface of the probe body. For example, the probe 2 may include a first body segment 21 with a first length L1 and a first width d1, a second body segment 22 with a second length L2 and a second width d2, and a tip segment 23 with a third length L3 and a third width d3. The first body segment 21, the second body segment 22, and the tip segment 23 are connected to one another and formed integrally. It is noteworthy that the probe processing apparatus 1 of the present disclosure may perform bending processing at any location on the first body segment 21, the second body segment 22, or the tip segment 23.

Furthermore, in the embodiment shown in the drawings, the first length L1 is greater than the second length L2, and the second length L2 is greater than the third length L3. Similarly, the first width d1 is greater than the second width d2, and the second width d2 is greater than the third width d3. However, the present disclosure does not impose any limitations on the lengths and widths of the probe 2. In other words, these dimensions may be adjusted and modified according to specific requirements in different applications.

As shown in FIG. 5, a conical tip extending from the outer surface of the first body segment 21 can form a first included angle θ₁, a conical tip extending from the outer surface of the second body segment 22 can form a second included angle θ₂, and a conical tip extending from the outer surface of the third body segment 23 can form a third included angle θ₃. The applicant has discovered that when θ₁, θ₂, and θ₃ satisfy the following formula, the probe 2 can simultaneously possess favorable contraction length and structural strength:

$${θ}_{1} = {θ}_{2} + θ 3 , cos {θ}_{1} = cos ( {θ}_{2} + {θ}_{3} ) = cos {θ}_{2} cos {θ}_{3} - sin {θ}_{2} sin {θ}_{3}$$

$$cos {θ}_{1} = \frac{{d}_{1}}{{L}_{1}} = \frac{{d}_{2}}{{L}_{2}} \times \frac{{d}_{3}}{{L}_{3}} - \frac{\sqrt{{L}_{2}^{2} - {d}_{2}^{2}}}{{L}_{2}} - \frac{\sqrt{{L}_{3}^{2} - {d}_{3}^{2}}}{{L}_{3}}$$

$$\frac{{d}_{1}}{{L}_{1}} = \frac{{d}_{2} {d}_{3}}{{L}_{2} {L}_{3}} - \frac{\sqrt{( {L}_{2}^{2} - {d}_{2}^{2} ) ( {L}_{3}^{2} - {d}_{3}^{2} )}}{{L}_{2} {L}_{3}}$$

$${L}_{2} {L}_{3} {d}_{1} = {L}_{1} {d}_{2} {d}_{3} - {{L}_{1} [ ( {L}_{2}^{2} - {d}_{2}^{2} ) ( {L}_{3}^{2} - {d}_{3}^{2} ) ]}^{\frac{1}{2}}$$

The present disclosure further provides a probe processing system, which includes the probe processing apparatus 1 disclosed herein. The probe processing system may include an image capturing device (e.g., a camera not shown in the drawings). During the processing procedure, the imaging surface (also referred to as the imaging plane) of the image capturing device may face the probe seat 10, the pushing element 115, the stopping mechanism 125, and the probe 2. In some embodiments, the orientation surface of the image capturing device may be aligned with the location on the probe 2 where processing is to be performed (e.g., the tip of the probe 2).

The image capturing device may be connected to an electronic device, such as a mobile terminal, tablet, desktop computer, or any other electronic equipment capable of performing data processing, and it may also be connected to a display device. Accordingly, the user can observe static or dynamic images of the probe 2 during the processing procedure through the display device. In some embodiments, the image capturing device may include a depth camera or at least one automatic optical recognition device. For example, it may comprise an automatic optical inspection system formed by multiple automatic optical inspection devices. This system differs from the conventional grayscale image correction concept in that it performs correction by detecting and adjusting the real light source (e.g., luminous flux, illuminance, etc.). In this way, the light source received by each automatic optical inspection device, as well as the images related to the probe 2, can achieve the same or substantially the same brightness, thereby improving the accuracy and consistency of inspection.

In some embodiments, the automatic optical inspection device may include at least one light source module, at least one imaging module, at least one photoelectric sensor (e.g., a photoelectric sensor or photodiode), and at least one information processing module. The primary function of the light source module is to emit visible or invisible light, or both, toward the probe 2. The imaging module is configured to receive the light reflected from the probe 2, ambient light, and image data. Moreover, according to actual needs, the light source module and the imaging module may be disposed on the same side of the probe 2 (referred to as a front-illumination light source configuration) or on different sides of the probe 2 (referred to as a back-illumination light source configuration). The light source module may also be disposed on the side of the probe 2, with the projected light being nearly parallel to the plane on which the probe 2 lies (referred to as side-illumination). In short, as long as the light projected by the light source module can sufficiently illuminate the designated location of the probe 2, and the corresponding light and image of the illuminated area can be effectively captured by the imaging module, the configuration is deemed acceptable.

The imaging module includes at least one lens and one imaging unit. The lens may consist of a single lens or multiple lenses with different structures. In addition, the lens may include other components, such as a voice coil motor used for moving the lenses. The imaging unit functions to acquire and generate images, and it may adopt various technical specifications, such as image sensors using Complementary Metal-Oxide Semiconductor (CMOS) or Charge-Coupled Device (CCD) technologies, as well as image processors. The imaging module is capable of guiding external light and images to the imaging unit via the lens, thereby obtaining clear and focused images for the user to acquire image data during the processing of the probe 2.

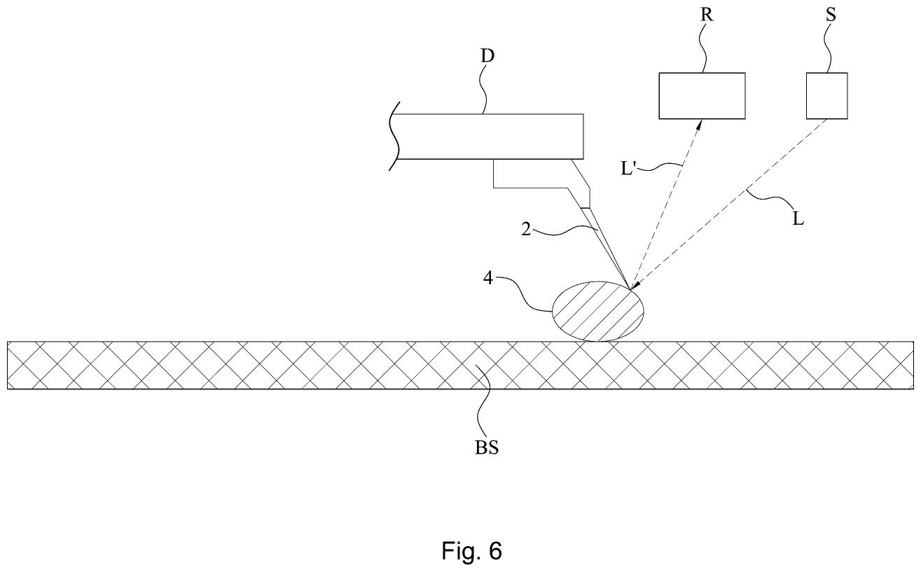

Please refer to FIG. 6, which illustrates a schematic view of the probe 2 of the present disclosure being applied in a detection device D. The detection device D is disposed on a base surface BS and includes at least a cantilever and a probe 2 of the present disclosure. In some embodiments, the probe 2 may be a bent probe formed by a bending process. During the detection process, the detection device D is disposed on the base surface BS to perform detection of the physical characteristics of the object 4 to be measured. The base surface BS may be a flat surface, a curved surface, an irregular non-planar surface, or a groove or protruding structure relative to its surrounding environment. Furthermore, the base surface BS may be composed of flexible materials, non-flexible materials, or a combination thereof. On the other hand, the object 4 may be a chip, wafer, transistor, integrated circuit, or other micro-nano electronic component. During detection, one or more light sources S emitting visible or/and invisible light, as well as one or more signal transceivers R, may be provided to collect physical characteristic information related to the object 4.

Specifically, when the probe 2 approaches or comes into contact with the surface of the object 4 to be measured, the light source S may be operated to emit a light beam L, which illuminates the surface of the object 4 to be measured and generates a reflected light beam L′. At this time, the receiver in the signal transceiver R may be configured to receive the reflected light beam L′, thereby obtaining optical signals associated with the object 4. Subsequently, the receiver R may transmit the received optical signals to an electronic device (such as a mobile terminal, tablet, desktop computer, or any other electronic equipment capable of performing data processing) via the transmitter of the signal transceiver for computational processing, thereby acquiring information related to the physical characteristics of the object 4.

In addition, although in the embodiment illustrated in FIG. 6 the object 4 to be measured and the detection device D are placed on the same surface, the object 4 and the detection device D may also be placed on two separate surfaces, which may be at different heights or positions.

In some embodiments, the detection device D may be a non-destructive detection tool, including but not limited to the following instruments: Atomic Force Microscope (AFM), Transmission Electron Microscope (TEM), Focused Ion Beam (FIB), Scanning Probe Microscopy (SPM), Electrostatic Force Microscopy (EFM), Scanning Capacitance Microscopy (SCM), and Scanning Ion Conductance Microscope (SICM).

The above embodiments merely describe the principle and effects of the present disclosure, instead of being used to limit the present disclosure. Therefore, persons skilled in the art can make modifications to and variations of the above embodiments without departing from the spirit of the present disclosure. The scope of the present disclosure should be defined by the appended claims.

What is claimed is:

1. A probe processing apparatus, comprising:
a probe seat having an opening configured to secure a probe therein;
a pushing element disposed on a first bracket, the first bracket being disposed on a first side of the probe seat and being configured to move relative to the probe seat; and
a stopping element disposed on a second bracket, the second bracket being positioned on a second side opposite to the first side of the probe seat and being configured to press against the probe fixed on the probe seat, wherein the pushing element is disposed at a first height, the stopping element is disposed at a second height, and the first height is higher than the second height;
wherein when the stopping element presses against the probe fixed on the probe seat from the second side, the pushing element is configured to move toward the probe seat from the first side and push to bend the probe.

2. The probe processing apparatus of claim 1, wherein the first bracket is disposed on a first sliding base, the first sliding base being slidable relative to a first rail installed on a first base.

3. The probe processing apparatus of claim 1, wherein the second bracket is disposed on a second sliding base, the second sliding base being slidable relative to a second rail installed on a second base.

4. The probe processing apparatus of claim 1, further comprising: a first sliding member disposed on the first bracket and slidable relative to a first slide rail arranged on the first bracket, wherein one end of the pushing element opposite to the probe seat is connected to the first sliding member.

5. The probe processing apparatus of claim 4, further comprising a first displacement adjusting member passing through a first through hole in the first bracket and configured to push the first sliding member.

6. The probe processing apparatus of claim 1, further comprising a second sliding member disposed on the second bracket and slidable relative to a second slide rail arranged on the second bracket, wherein one end of the stopping element opposite to the probe seat is connected to the second sliding member.

7. The probe processing apparatus of claim 6, further comprising a second displacement adjusting member passing through a second through hole in the second bracket and configured to push the second sliding member.

8. The probe processing apparatus of claim 1, further comprising:
a slide rail assembly disposed adjacent to the probe seat, the slide rail assembly comprising a slide rail base and a slide rail cover slidable relative to the slide rail base; and
a connecting plate connected to the slide rail cover, wherein the probe seat is supported on the connecting plate.

9. The probe processing apparatus of claim 8, wherein the slide rail assembly further comprises a connecting bracket disposed on the slide rail base, and wherein the probe processing apparatus further comprises a height adjusting member passing through a third through hole in the connecting bracket and configured to push the slide rail cover.

10. The probe processing apparatus of claim 9, further comprising: a supporting plate attached to the slide rail base of the slide rail assembly and configured to support the slide rail assembly.

11. The probe processing apparatus of claim 1, wherein the pushing element has a first groove at an end facing the probe seat, the first groove being configured to receive the probe, and the stopping element has a second groove at an end facing the probe seat, the second groove being configured to receive the probe.

12. The probe processing apparatus of claim 11, wherein the first groove of the pushing element and the second groove of the stopping element are configured to respectively engage with the probe.

13. The probe processing apparatus of claim 11, wherein at least one of the first groove of the pushing element and the second groove of the stopping element is substantially V-shaped.

14. The probe processing apparatus of claim 1, wherein an inclined surface is formed at an end of the pushing element facing the probe seat.

15. The probe processing apparatus of claim 1, further comprising a supporting member having a U-shaped opening, the supporting member being disposed on the second bracket and configured to accommodate the stopping element therein.

16. The probe processing apparatus of claim 1, wherein a bottom surface of the pushing element is substantially aligned with a top surface of the stopping element.

17. A probe processing apparatus, comprising:
a probe seat configured to hold a probe, wherein when the probe is held on the probe seat, the probe extends substantially in a vertical direction;
a stopping element, wherein when the probe is held on the probe seat, the stopping element is configured to abut the probe at a first height; and
a pushing element configured to realize a movement in a horizontal direction, wherein when the stopping element abuts the probe, the pushing element is configured to contact and push the probe at a second height by the movement, so as to deform the probe;
wherein the second height is higher than the first height;
wherein the probe comprises a probe used for detecting micro-nano components.

18. The probe processing apparatus of claim 17, wherein the pushing element comprises a first groove configured to receive the probe when the second stopping element abuts the probe.

19. The probe processing apparatus of claim 17, wherein the pushing element comprises a first groove configured to substantially engage with the probe when the stopping element abuts the probe.

20. A method for processing a probe, comprising:
holding a probe on a probe seat, wherein the probe held on the probe seat extends substantially in a vertical direction;
providing a stopping element to abut the probe at a first height;
providing a pushing element to contact the probe at a second height, wherein the second height is higher than the first height; and
moving the pushing element in a horizontal direction such that the pushing element pushes the probe at the second height and deforms the probe;
wherein the probe comprises a probe used for detecting micro-nano components.
